(19) United States
(12) Patent Application Publication
(10) Pub. No.: US 2010/0237461 A1
(43) Pub. Date: Sep. 23, 2010

(54) SEMICONDUCTOR PACKAGE SUBSTRATE INCLUDING FUSES, SEMICONDUCTOR DEVICE PACKAGE, SEMICONDUCTOR MODULE AND ELECTRONIC APPARATUS INCLUDING THE SAME

(75) Inventor: Jae-Hyuk LEE, Hwasung-City, (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/727,418

(22) Filed: Mar. 19, 2010

(30) Foreign Application Priority Data
Mar. 19, 2009 (KR) 10-2009-0023534

(51) Int. Cl. H01L 23/525

(52) U.S. Cl. 257/529; 257/690; 257/734; 257/E23.149

(57) ABSTRACT

A semiconductor device package, and a semiconductor module and an electronic apparatus including the semiconductor device package are provided. The semiconductor device package includes a package substrate, first pads and second pads disposed on a first surface of the package substrate and fuses corresponding to the second pads, the fuses being disposed on a second surface of the package substrate. First and second semiconductor chips including a plurality of chip pads are disposed on the first surface of the package substrate and the first pads are electrically connected to both one of the chip pads of the first semiconductor chip and one of the chip pads of the second semiconductor chip, wherein the second pads are selectively electrically connected to one of the chip pads of the first semiconductor chip or one of the chip pads of the second semiconductor chip.

### PRIORITY STATEMENT

This application claims priority under 35 U.S.C. §119 from Korean Patent Application No. 10-2009-0023534, filed on Mar. 19, 2009, the contents of which are hereby incorporated herein by reference in their entirety.

### SUMMARY

Illustrative embodiments relate to a semiconductor device package including a package substrate having fuses and a plurality of semiconductor chips, and a semiconductor module and an electronic apparatus including the semiconductor device package.

Electronic technology including semiconductor technology could be said to be moving toward processing larger amounts of information at higher speeds. Accordingly, various techniques have been researched and applied in electronic technology fields to which semiconductors are applied, and thereby developed. As one example, a technique for integrating a plurality of semiconductor devices into one semiconductor device package has been developed. This technique involves not only increasing a storage capacity of a semiconductor memory device, but also integrating a microprocessor and various semiconductor memory devices into one semiconductor device package. That is, one semiconductor device package not only serves as one high-capacity semiconductor device, but also operates as one complete electronic system.

Illustrative embodiments provide a package substrate used in a semiconductor device package which can selectively deactivate semiconductor chips among a plurality of semiconductor chips.

Illustrative embodiments also provide a semiconductor device package which can selectively deactivate semiconductor chips among a plurality of semiconductor chips.

Illustrative embodiments also provide a semiconductor module including a semiconductor device package which can selectively deactivate semiconductor chips among a plurality of semiconductor chips.

Illustrative embodiments also provide an electronic apparatus including a semiconductor device package which can selectively deactivate semiconductor chips among a plurality of semiconductor chips.

Illustrative embodiments are directed to a semiconductor device package including a package substrate including first pads and second pads on a first surface of the package substrate, and fuses corresponding to the second pads on a second surface of the package substrate, and first and second semiconductor chips including, a plurality of chip pads on the first surface of the package substrate and being electrically connected to the first pads and the second pads, respectively, and wherein the first pads are electrically connected to both one of the chip pads of the first semiconductor and one of the chip pads of the second semiconductor, wherein the second pads are selectively electrically connected to one of the chip pads of the first semiconductor or one of the chip pads of the second semiconductor.

Illustrative embodiments are directed to a semiconductor device package including a package substrate, the package substrate including, a plurality of pads on a first surface of the package substrate, and a plurality of fuses on a second surface of the package substrate and corresponding to the plurality of pads, wherein the plurality of pads are electrically connected to the plurality of fuses through vias, respectively, wherein the plurality of fuses are electrically connected to each other, and at least two semiconductor chips on the first surface of the package substrate, the semiconductor chips including, a plurality of chip pads electrically connected to the plurality of pads.

Illustrative embodiments are directed to a semiconductor package substrate including a first surface and a second surface opposite to the first surface, first pads and second pads on the first surface, fuses on the second surface corresponding to the second pads respectively, and vias electrically connecting the second pads to the fuses respectively.

Illustrative embodiments are directed to a semiconductor package substrate including a first surface and a second surface opposite to the first surface, a plurality of pads on the first surface, and a plurality of fuses on the second surface, corresponding to the plurality of the pads respectively, wherein the plurality of the pads are electrically connected to the plurality of the fuses through vias, and wherein the fuses are electrically connected to each other.

Illustrative embodiments are directed to a semiconductor module including a module substrate, and a plurality of semiconductor device packages on the module substrate, wherein at least one of the semiconductor device packages comprises, a package substrate, the package substrate including, a plurality of pads on a first surface of the package substrate, and a plurality of fuses on a second surface of the package substrate and corresponding to the plurality of pads, wherein the plurality of pads are electrically connected to the plurality of fuses through vias, respectively, wherein the plurality of fuses are electrically connected to each other, and at least two semiconductor chips on the first surface of the package substrate, the semiconductor chips including a plurality of chip pads electrically connected to the plurality of pads.

Illustrative embodiments are directed to a semiconductor module including a module substrate, and a plurality of semiconductor device packages on the module substrate, wherein at least one of the semiconductor device packages comprises, a package substrate, the package substrate including, a plurality of pads on a first surface of the package substrate, and a plurality of fuses on a second surface of the package substrate and corresponding to the plurality of pads, wherein the plurality of pads are electrically connected to the plurality of fuses through vias, respectively, wherein the plurality of fuses are electrically connected to each other, and at least two semiconductor chips on the first surface of the package substrate, the semiconductor chips including a plurality of chip pads electrically connected to the plurality of pads.

Illustrative embodiments are directed to an electronic apparatus including a memory unit including at least one semiconductor device package, a controller to control the electronic apparatus being electrically connected to the memory unit, and an input/output unit electrically connected to the controller, and wherein the semiconductor device package includes a package substrate, the package substrate includes a plurality of pads on a first surface of the package substrate, and a plurality of fuses on a second surface of the package substrate and corresponding to the plurality of pads, wherein the plurality of pads are electrically connected to the plurality of fuses through vias, respectively, wherein the plurality of fuses are electrically connected to each other, and at least two semiconductor chips on the first surface of the package substrate, the semiconductor chips including a plurality of chip pads electrically connected to the plurality of pads.

Illustrative embodiments are directed to an electronic apparatus including a memory unit including at least one semiconductor device package, a controller to control the electronic apparatus being electrically connected to the memory unit, and an input/output unit electrically connected to the controller, and wherein the semiconductor device package includes a package substrate, the package substrate includes a plurality of pads on a first surface of the package substrate, and a plurality of fuses on a second surface of the package substrate and corresponding to the plurality of pads, wherein the plurality of pads are electrically connected to the plurality of fuses through vias, respectively, wherein the plurality of fuses are electrically connected to each other, and at least two semiconductor chips on the first surface of the package substrate, the semiconductor chips including a plurality of chip pads electrically connected to the plurality of pads.

### BRIEF DESCRIPTION OF THE DRAWINGS

Illustrative embodiments are described in further detail below with reference to the accompanying drawings. It should be understood that various aspects of the drawings may have been exaggerated for clarity.

FIG. 1 is a schematic plan view of a semiconductor device package according to an illustrative embodiment.

FIG. 2 is a vertical sectional view of the semiconductor device package taken along line II-II′ of FIG. 1.

FIG. 3 is a diagram illustrating a surface of the semiconductor device package according to an illustrative embodiment, which is connected to a system board.

FIGS. 4(A), 4(B), 4(C) and 4(D) illustrate the shapes of various fuses according to illustrative embodiments.

FIGS. 5A and 5B illustrate connection structures of a package substrate including fuses according to an illustrative embodiment.

FIG. 6 is a vertical sectional view of a semiconductor device package according to another illustrative embodiment.

FIG. 7 is a schematic view of a semiconductor module according to an illustrative embodiment.

FIG. 8 is a block diagram illustrating an electronic apparatus according to an illustrative embodiment.

### DETAILED DESCRIPTION

Various illustrative embodiments will now be described more fully with reference to the accompanying drawings in which some illustrative embodiments are shown. In the drawings, the thicknesses of layers and regions may be exaggerated for clarity.

Detailed illustrative embodiments are disclosed herein. However, specific structural and functional details disclosed herein are merely representative for purposes of describing illustrative embodiments. Illustrative embodiments may have many alternate forms and the illustrative embodiments set forth herein should not be construed as limiting.

Accordingly, while embodiments are capable of various modifications and alternative forms, illustrative embodiments thereof are shown by way of example in the drawings and will herein be described in detail. It should be understood, however, that there is no intent to limit illustrative embodiments to the particular forms disclosed, but on the contrary, illustrative embodiments are to cover all modifications, equivalents, and alternatives falling within the scope of the inventive concept, as defined by the appended claims. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of illustrative embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of illustrative embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Illustrative embodiments are described herein with reference to cross-sectional illustrations that are schematic illustrations of embodiments (and intermediate structures).

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe illustrative embodiments, various aspects will be described in detail with reference to the attached drawings. However, the inventive concept defined by the appended claims is not limited to illustrative embodiments described.

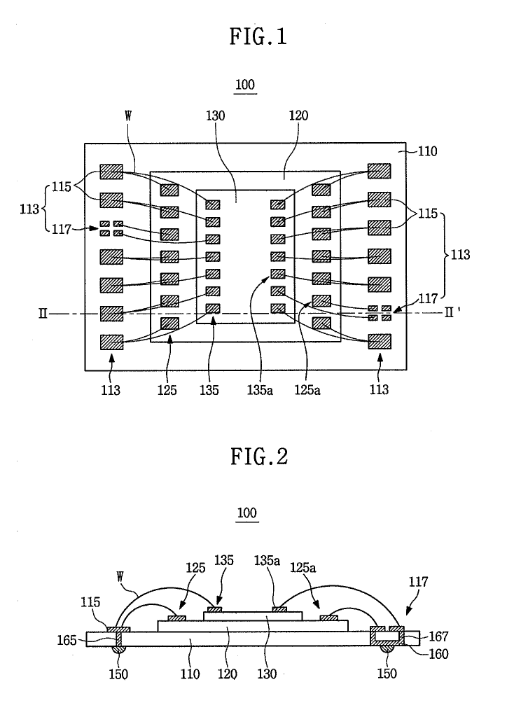

FIG. 1 is a schematic plan view of a semiconductor device package according to an illustrative embodiment and FIG. 2 is a cross-sectional view of the semiconductor device package taken along line II-II′ of FIG. 1. Referring to FIGS. 1 and 2, the semiconductor device package 100 according to the illustrative embodiment includes a package substrate 110, a first semiconductor chip 120 disposed on the package substrate 110, and a second semiconductor chip 130 disposed on the first semiconductor chip 120. The package substrate 110 includes package pads 113, and the first and second semiconductor chips 120 and 130 include first and second chip pads 125 and 135, respectively. The package pads 113 include macro pads 115 and at least two branch pads 117, and the branch pads 117 are electrically connected to a first chip pad 125a of the first semiconductor chip 120 and a second chip pad 135a of the second semiconductor chip 130 exclusively from each other. FIG. 1 illustrates a case in which the respective pads 115, 117, 125, 125a, 135, and 135a are electrically connected through bonding wires W. However, the respective pads may be electrically connected by solders using grid arrays such as a flip chip bonding. The macro pads 115 may be formed on a first surface of the package substrate 110 and electrically and/or physically connected to connectors 150 formed on a second surface of the package substrate 110 through macro vias 165.

The branch pads 117 may be formed on a first surface of the package substrate 110 and understood by separating one macro pad 115 into two or more parts. The branch pads 117 may be physically and electrically connected to each other using vias 167 formed in the package substrate 110. More specifically, the package substrate 110 has connectors 150 such as solder lands or solder balls formed on the other surface thereof, the connectors 150 being used for electrically connecting the package substrate 110 to a module board, a system board or the like. Since the branch pads 117 have a similar function, they are physically and electrically connected to one of the connectors 150. Therefore, the branch pads 117 may be separately formed on one surface of the package substrate 110, on which the semiconductor chips are disposed. Further, the branch pads 117 may be integrally formed on the other surface of the package substrate 110, which is connected to the module board or the system board.

The branch pads 117 may be formed on the first surface of the package substrate 110 and electrically and/or physically connected to the connectors 150 formed on the second surface of the package substrate 110 through branch vias 167 and/or fuses 160. The branch vias 167 may correspond to the branch pads 117, respectively. The fuses 160 may be exposed. Each of the branch pads 117 may be exclusively connected to the semiconductor chips 120 and 130. The number of the branch pads 117 is greater than the number of the semiconductor devices 120 and 130.

In particular, the branch pads 117 may supply operating voltages Vdd or Vss to the first and second semiconductor chips 120 and 130. When an operating voltage is not supplied to a specific semiconductor chip, a controller that controls the semiconductors may recognize that the corresponding semiconductor chip is not present. That is, in order to deactivate the corresponding semiconductor chip, not all electrical signal transmission lines need to be cut. FIG. 1 illustrates that all the macro pads 115, excluding the branch pads 117, are electrically connected to the first and second semiconductor chips 120 and 130. However, depending on the particular application, the macro pads 115 may be electrically connected to any one of the first and second semiconductor chips 120 and 130. In a step of marking a specific semiconductor chip after the semiconductor chip is deactivated and a packaging process is performed, the marking may be performed in a modified capacity and the semiconductor chip of an illustrative embodiment may then be used together with a different semiconductor device.

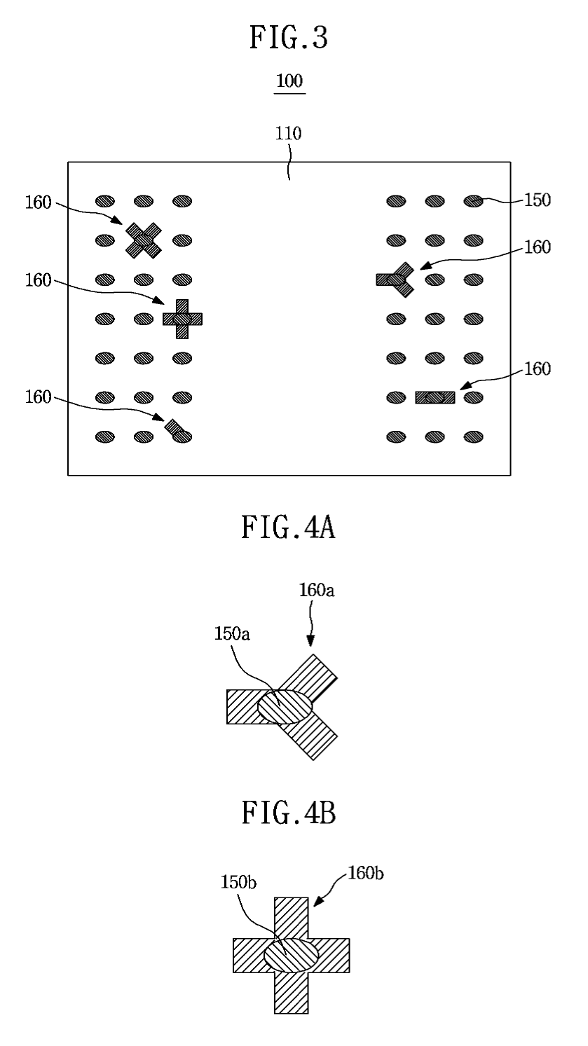

FIG. 3 is a schematic plan view illustrating a surface of the semiconductor device package according to an illustrative embodiment, which is connected to the system board. Referring to FIG. 3, the semiconductor device package 100 according to the illustrative embodiment includes the connectors 150 formed on one surface thereof and the fuses 160, each of which is electrically connected to any one of the connectors 150. The fuses 160 may be formed at a higher or lower position than the surface of the package substrate 110 and may be exposed to the outside. That is, the fuses 160 may be physically cut by a laser or the like.

When a fuse 160 is cut, an electrical signal is not supplied to a branch via 167 and a branch pad 117 connected to the cut fuse 160. Therefore, a semiconductor chip electrically connected to the cut fuse 160 does not operate. When the fuse 160 is cut, a semiconductor chip controller or semiconductor module controller considers that a specific semiconductor chip is originally absent from the semiconductor device package 100, and then controls the semiconductor device package 100.

According to conventional devices, when such a fuse is not cut, and if a specific semiconductor chip has caused an abnormality, the entire semiconductor device package would malfunction. The entire malfunctioning semiconductor device package would then be discarded.

In the semiconductor device package 100 according to an illustrative embodiment, however, when a specific semiconductor chip causes an abnormality, a fuse 160 electrically connected to the semiconductor chip may be cut, which makes it possible to cause the controller to recognize that the semiconductor chip is absent. Therefore, the entire semiconductor device package 100 does not malfunction, and is not discarded because of the specific semiconductor chip.

Returning to FIG. 3, the fuses 160 are formed in such a manner that each of them is electrically connected to one connector 150 on the package substrate 110 and is electrically insulated from the other connectors 150.

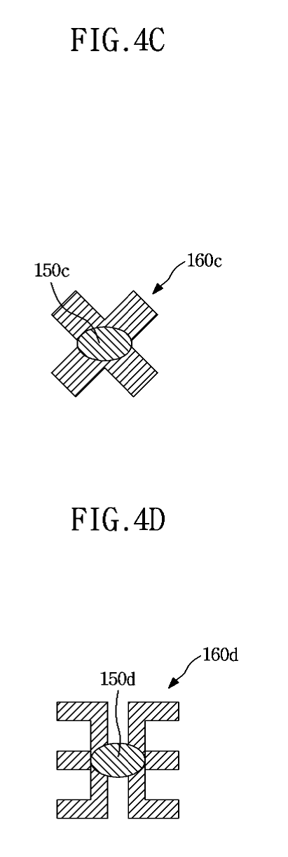

FIGS. 4(A), 4(B), 4(C) and 4(D) illustrate the shapes of various fuses according to illustrative embodiments showing disposition forms of the connectors 150 and the fuses 160 which may be formed on the package substrate 110. FIG. 4(A) illustrates an arrangement form of connectors 150a and fuses 160a including three branch vias and branch pads. FIG. 4(B) and FIG. 4(C) illustrate, respectively, arrangement forms of connectors 150b and 150c and fuses 160b and 160c including four branch vias and branch pads. FIG. 4(D) illustrates an arrangement form of connectors 150d and fuses 160d including six branch vias and branch pads. FIGS. 4(A), 4(B), 4(C) and 4(D) conceptually illustrate the arrangement forms of the connectors 150 and the fuses 160. That is, it can be inferred that according to illustrative embodiments a larger number of fuses 160 may be disposed in various forms.

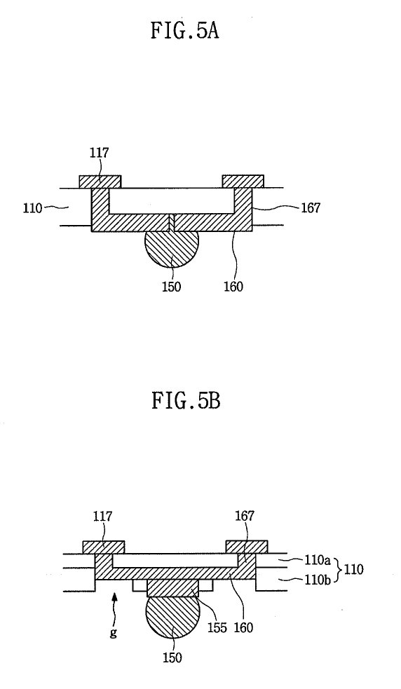

FIGS. 5A and 5B illustrate connection structures of the package substrate including fuses according to an illustrative embodiment. First, referring to FIG. 5A, the connection structure of the package substrate 110 according to an illustrative embodiment includes branch pads 117 disposed on one surface of the package substrate 110, branch vias 167 electrically connected to the branch pads 117, respectively, fuses 160 electrically connected to the branch vias 167, and a connector 150 electrically connected to the fuses 160. In the package substrate 110, one surface on which the branch pads 117 are disposed is where semiconductor chips are disposed, and the other surface on which the connectors 150 are disposed is connected to a module board or a system board. The branch vias 167 are formed through the package substrate 110. The fuses 160 may be formed so as to protrude from the surface of the package substrate 110. The fuses 160 may be integrally formed or separately formed so as to be electrically connected to each other and the connector 150. FIG. 5A illustrates that the fuses 160 are separately formed. FIG. 2 has already shown that the fuses are integrally formed.

Referring to FIG. 5B, the connection structure of the package substrate 110 according to another illustrative embodiment includes branch pads 117 disposed on one surface of the package substrate 110, branch vias 167 electrically connected to the branch pads 117, respectively, fuses 160 electrically connected to the branch vias 167, and connectors 150 electrically connected to the fuses 160. The fuses 160 are formed inside the package substrate 110, and a groove g is formed on the package substrate 110 such that the fuses 160 are exposed to the groove g. The connection structure of the package substrate 110 according to this illustrative embodiment will be more useful when the package substrate 110 is a multilayered structure. FIG. 5B illustrates that the package substrate 110 includes an upper layer portion 110a and a lower layer portion 110b. Therefore, the fuses 160 may include exposed portions and unexposed portions. FIG. 5B illustrates that the unexposed fuses 160 are integrally formed according to one illustrative embodiment. However, the fuses 160 may be separated as shown with respect to the illustrative embodiment in FIG. 5A.

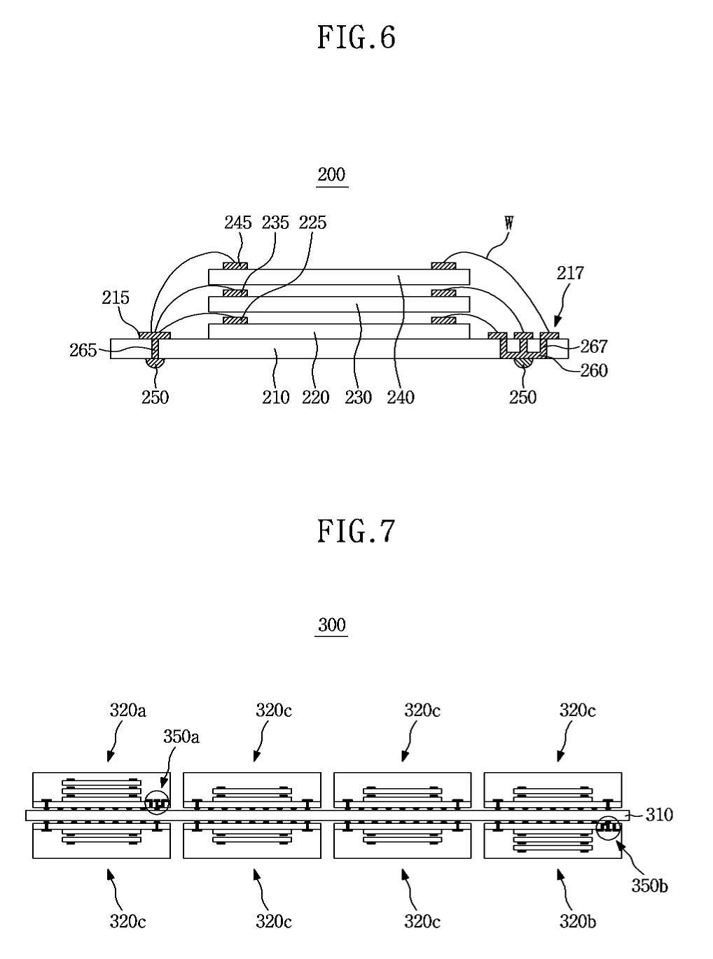

FIG. 6 is a vertical sectional view of a semiconductor device package according to another illustrative embodiment. Referring to FIG. 6, the semiconductor device package 200 according to this illustrative embodiment includes semiconductor chips 220, 230, and 240 having substantially the same size and disposed on a package substrate 210. The package substrate 210 includes package pads 215 and 217, and the semiconductor chips 220, 230, and 240 include chip pads 225, 235, and 245, respectively. The package pads 215 and 217 include macro pads 215 and one or more branch pads 217, and the branch pads 217 are electrically connected to the respective semiconductor chips 220, 230, and 240 exclusively from each other. In the illustrative embodiment of FIG. 6, it is illustrated that three semiconductor chips 220, 230, and 240 are stacked, in order to show that a plurality of semiconductor chips can be stacked. However, it can be inferred that a larger or smaller number of semiconductor chips can be stacked consistent with various illustrative embodiments.

Returning to FIG. 6, the macro pad 215 is electrically connected to the respective semiconductor chips 220, 230, and 240, and each of the branch pads 217 is electrically connected to one of the semiconductor chips 220, 230, and 240. The macro pad 215 may be electrically connected to one connector 250 through one macro via 265. The branch pads 217 may be electrically connected to one connector 250 through branch vias 267 and fuses 260, respectively.

FIG. 7 is a schematic view of a semiconductor module according to an illustrative embodiment. To facilitate understanding of the illustrative embodiment of FIG. 7, the insides of semiconductor device packages 320a, 320b and 320c are shown. Specifically, FIG. 7 schematically illustrates that semiconductor device packages 320a and 320b according to the illustrative embodiment are disposed on one module substrate 310 together with different semiconductor device packages 320c. Referring to FIG. 7, the semiconductor module 300 according to the illustrative embodiment includes a plurality of semiconductor device packages 320a, 320b and 320c disposed on the module substrate 310. At least one of the semiconductor device packages 320a, 320b and 320c includes fuses 350a and 350b disposed on a package substrate. Specifically, the semiconductor device packages include the fuses 350a and 350b connected to semiconductor chips having abnormalities. Therefore, as the fuses 350a and 360a are cut, it is recognized that semiconductor chips which are not electrically connected to connection parts are absent. Accordingly, the semiconductor device packages 320a and 320b can be implemented as a module together with semiconductor device packages 320c. In this illustrative embodiment, a memory module is illustrated as the semiconductor module 300 in order to facilitate understanding of the illustrative embodiment.

In a semiconductor device package that is not consistent with illustrative embodiments, when an abnormality occurs in a semiconductor chip after the packaging process, a fuse may be cut in a state in which the semiconductor chip is packaged. Then, the abnormal semiconductor chip can be deactivated, and the semiconductor chip package can be continuously used.

On the other hand, in a semiconductor device package according to illustrative embodiments, when a specific semiconductor chip causes an abnormality after a packaging process, the semiconductor chip can be deactivated so that the semiconductor device package can be continuously used. Therefore, the yield and efficiency of the semiconductor device package can increase and the price of products can be reduced.

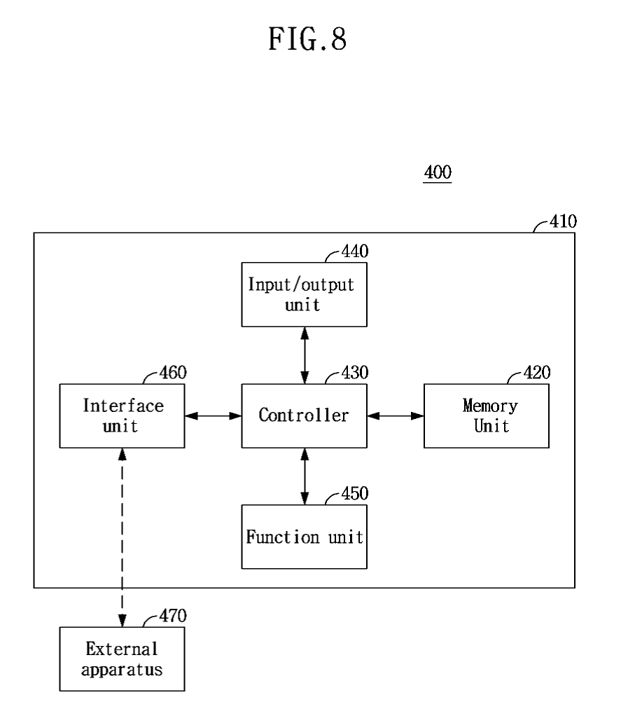

FIG. 8 is a block diagram illustrating an electronic apparatus according to an illustrative embodiment. The electronic apparatus 400 may include a housing 410 to accommodate elements or units of the electronic apparatus 400, a memory unit 420, a controller 430, an input/output unit 440, a function unit 450, and/or an interface unit 460 to communicate with an external apparatus 470 through a wired or wireless communication line to receive and transmit data or signals. At least one of the semiconductor device packages and the semiconductor modules illustrated in FIGS. 1-7 can be used as the memory unit 420. Therefore, the memory unit 420 can be referred to as the semiconductor packages or semiconductor modules. The memory unit 420 can be connected to corresponding terminals of controller 430 to receive data to be stored or processed in the semiconductor circuit or to transmit the stored or processed data. The data may be input through the input/output unit 440, the function unit 450, and/or the external apparatus 470 through the interface unit 460. The function unit 450 may be a unit configured to perform a function or operation of the electronic apparatus 400. For example, when the electronic apparatus 400 is a computer, an image processing apparatus, a television apparatus, or a monitor apparatus, the function unit 450 may be a display unit configured to display an image and/or an audio output unit configured to generate a signal or sound according to the data. By way of further illustration, when the electronic apparatus is a mobile phone, the function unit 450 may be a mobile phone function unit configured to perform a mobile phone function, for example, dialing, text messaging, photographing using a camera unit formed on the housing 410, audio and video data processing to be displayed on a display unit formed on the housing 410, etc. When the electronic apparatus is an image forming or scanning apparatus, the function unit 450 may be an image forming unit configured to feed a printing medium, to form or print an image on the printing medium, or to scan a document or picture to be stored in the memory unit. When the electronic apparatus 400 is a camera or camcorder, the function unit 450 may be a unit configured to photograph an image as a movie or a still image. The controller 430 controls elements and units of the electronic apparatus 400 and may be, for instance, a processor. At least one of the semiconductor chip, the semiconductor chips, and the semiconductor package illustrated in FIGS. 1-7 can be used as the controller 430. Therefore, the controller 430 can be referred to as the semiconductor chip, the semiconductor chips, the semiconductor package, or a semiconductor package unit. The controller 430 may be connected to corresponding terminals of the memory unit 420 or other units, for example, the input/output unit 440, the function unit 450, and/or the interface unit 460, to transmit or receive data to or from the semiconductor circuit of the memory unit 420, or other units.

The foregoing is representative of illustrative embodiments and is not to be construed as limiting such embodiments. Although a few illustrative embodiments have been described, those skilled in the art will readily appreciate that many modifications are possible in illustrative embodiments without materially departing from the novel teachings and advantages. Accordingly, all such modifications are intended to be included within the scope of this inventive concept as defined in the appended claims. In the claims, means-plus-function clauses are intended to cover the structures described herein as performing the recited function, and not only structural equivalents but also equivalent structures. Therefore, it is to be understood that the foregoing is representative of various illustrative embodiments and is not to be construed as limiting the specific illustrative embodiments disclosed, and that modifications to the disclosed illustrative embodiments, as well as other embodiments, are intended to be included within the scope of the appended claims.

1. A semiconductor device package comprising:
a package substrate;
first pads and second pads, wherein the first pads and the second pads are disposed on a first surface of the package substrate; and
fuses corresponding to the second pads, wherein the fuses are disposed on a second surface of the package substrate;
a first semiconductor chip comprising first chip pads; and
a second semiconductor chip comprising second chip pads;
wherein the first semiconductor chip is disposed on the first surface of the package substrate,
wherein each one of the first pads is electrically connected to both one of the first chip pads and one of the second chip pads,
wherein each one of the second pads is configured to be selectively electrically connected to one of the first chip pads or one of the second chip pads.

2. The semiconductor device package according to claim 1, wherein the first pads are not electrically connected to each other, and
wherein at least two of the second pads are electrically connected to each other.

3. The semiconductor device package according to claim 2, wherein the at least two of the second pads are electrically connected to each other through the fuses.

4. The semiconductor device package according to claim 3, further comprising vias, wherein respective vias electrically connect the at least two of the second pads to the fuses.

5. The semiconductor device package according to claim 3, further comprising connectors disposed on the second surface of the package substrate.

6. The semiconductor device package according to claim 5, wherein the connectors electrically connect the first pads and the second pads to at least one of an external module board or system board.

7. The semiconductor device package according to claim 6, wherein the fuses are electrically connected to each other through one of the connectors.

8. The semiconductor device package according to claim 1, wherein the package substrate is a multilayered structure, and
wherein the fuses are formed inside the package substrate.

9. The semiconductor device package according to claim 8, wherein the package substrate comprises a groove exposing the fuses.

10. The semiconductor device package according to claim 1, wherein the second pads transfer an operating voltage.

11. A semiconductor device package comprising:
a package substrate;
a plurality of pads disposed on a first surface of the package substrate; a plurality of fuses disposed on a second surface of the package substrate and corresponding to the plurality of pads; and
at least two semiconductor chips disposed on the first surface of the package substrate, each of the at least two semiconductor chips including a plurality of chip pads electrically connected to the plurality of pads;
wherein the plurality of pads are electrically connected to the plurality of fuses through respective vias,
wherein the plurality of fuses are electrically connected to each other.

12. The semiconductor device package according to claim 11, wherein each one of the plurality of pads is exclusively connected to one of the at least two semiconductor chips.

13. A semiconductor package substrate comprising:
a first surface;
a second surface opposite to the first surface;
first pads and second pads, wherein the first pads and the second pads are disposed on the first surface;
fuses disposed on the second surface, wherein the fuses correspond to the second pads, respectively; and
vias, wherein respective vias electrically connect the second pads to the fuses.

14. The semiconductor package substrate according to claim 13, wherein the semiconductor package substrate is a multilayered structure, and
wherein the fuses are formed inside the multilayered semiconductor package substrate.

15. The semiconductor package substrate according to claim 14, further comprising a groove exposing the fuses.

16. A semiconductor package substrate comprising:
a first surface;
a second surface opposite to the first surface;
a plurality of pads disposed on the first surface; and
a plurality of fuses disposed on the second surface and corresponding to the plurality of pads, respectively,
wherein the plurality of pads are electrically connected to the plurality of fuses through respective vias, and
wherein the plurality of fuses are electrically connected to each other.

17. A semiconductor module comprising,
a module substrate; and
a plurality of semiconductor device packages disposed on the module substrate,
wherein at least one of the plurality of semiconductor device packages comprises:
a package substrate;
first pads and second pads, wherein the first pads and the second pads are disposed on a first surface of the package substrate; and
fuses corresponding to the second pads, wherein the fuses are disposed on a second surface of the package substrate;
a first semiconductor chip comprising first chip pads; and
a second semiconductor chip comprising second chip pads;
wherein the first semiconductor chip is disposed on the first surface of the package substrate,
wherein each one of the first pads is electrically connected to both one of the first chip pads and one of the second chip pads,
wherein each one of the second pads is configured to be selectively electrically connected to one of the first chip pads or one of the second chip pads.

18. A semiconductor module comprising,
a module substrate; and
a plurality of semiconductor device packages disposed on the module substrate,
wherein at least one of the plurality of semiconductor device packages comprises:
a package substrate;
a plurality of pads disposed on a first surface of the package substrate;
a plurality of fuses disposed on a second surface of the package substrate and corresponding to the plurality of pads; and
at least two semiconductor chips disposed on the first surface of the package substrate, each of the at least two semiconductor chips including a plurality of chip pads electrically connected to the plurality of pads;
wherein the plurality of pads are electrically connected to the plurality of fuses through respective vias,
wherein the plurality of fuses are electrically connected to each other.

19. An electronic apparatus comprising:
a memory unit including at least one semiconductor device package;
a controller configured to control the electronic apparatus, the controller being electrically connected to the memory unit; and
an input/output unit electrically connected to the controller, wherein the semiconductor device package comprises:
a package substrate;
first pads and second pads, wherein the first pads and the second pads are disposed on a first surface of the package substrate; and
fuses corresponding to the second pads, wherein the fuses are disposed on a second surface of the package substrate;
a first semiconductor chip comprising first chip pads; and
a second semiconductor chip comprising second chip pads;
wherein the first semiconductor chip is disposed on the first surface of the package substrate,
wherein each one of the first pads is electrically connected to both one of the first chip pads and one of the second chip pads,
wherein each one of the second pads is configured to be selectively electrically connected to one of the first chip pads or one of the second chip pads.

20. An electronic apparatus comprising:
a memory unit including at least one semiconductor device package;
a controller configured to control the electronic apparatus, the controller being electrically connected to the memory unit; and
an input/output unit electrically connected to the controller, wherein the at least one semiconductor device package comprises:
a package substrate;
a plurality of pads disposed on a first surface of the package substrate;
a plurality of fuses disposed on a second surface of the package substrate and corresponding to the plurality of pads; at least two semiconductor chips disposed on the first surface of the package substrate, the semiconductor chips including a plurality of chip pads electrically connected to the plurality of pads,
wherein the plurality of pads are electrically connected to the plurality of fuses through respective vias,
wherein the plurality of fuses are electrically connected to each other.

21. The semiconductor device package according to claim 1, wherein the semiconductor device package is configured such that, if the fuses are open, then one of the first semiconductor chip and the second semiconductor chip is selectively deactivated, without deactivating the other one of the first semiconductor chip and the second semiconductor chip.
